(19) United States
(12) Patent Application Publication
(10) Pub. No.: US 2005/0164460 A1
(43) Pub. Date: Jul. 28, 2005

(54) Salicide process for metal gate CMOS devices

(75) Inventors: Shajan Mathew, Singapore (SG); Lakshmi Kanta Bera, Singapore (SG)

Correspondence Address: STEPHEN B. ACKERMAN, 28 DAVIS AVENUE, POUGHKEEPSIE, NY, 12603, US

(73) Assignee: Agency For Science, Technology And Research

(21) Appl. No.: 10/763,304

(22) Filed: Jan. 23, 2004

(51) Int. Cl. H01L 21/00; H01L 21/336

(52) U.S. Cl. 438/304

(57) ABSTRACT

A process of forming metal silicide on specific regions of a MOSFET device without degrading a MOSFET metal gate structure during a wet etch cycle of a self-aligned metal silicide (SALICIDE) procedure, has been developed. The process features protecting or encapsulating the metal gate structure prior to a wet etch procedure used to remove unreacted metal after metal silicide formation. This is accomplished via use of an amorphous silicon shape initially defined on an underlying metal gate structure, allowing the salicide procedure to form metal silicide on the top surface of the gate structure. The metal gate structure now featuring an overlying metal silicide shape and featuring overlying composite insulator sidewall spacers, can be subjected to a salicide wet etch procedure without risk of metal gate erosion.

### BACKGROUND OF THE INVENTION

(1) Field of the Invention

The present invention relates to methods used to fabricate semiconductor devices, and more specifically to a method of forming self-aligned metal silicide (SALICDE) regions for complimentary metal oxide semiconductor (CMOS) devices.

(2) Description of Prior Art

To continually enhance semiconductor device performance sub-90 nm metal oxide semiconductor field effect transistor (MOSFET) devices are now being fabricated. Advances in specific semiconductor fabrication disciplines such as photolithography and dry etching have allowed sub-90 nm MOSFET devices featuring narrow channel lengths to be routinely obtained. However in addition to breakthroughs in process disciplines sub-90 nm devices are also being fabricated using materials such as high dielectric constant (high k) gate insulator layers as well as metal gate structures, which offer enhanced performance when compared to conventional counterparts such as silicon dioxide gate insulator layers and polysilicon gate structures. High k layers allow electrically thinner gate insulator layers to be employed with a reduced risk of leakage when compared to silicon dioxide gate insulator counterparts, while metal gate structures help to reduce gate dielectric thickness by avoiding depletion effects present in polysilicon gates and offer decreased word line resistance when compared to more resistive polysilicon gate structures. To decrease word line resistance metal silicide regions are formed on the polysilicon gate structures, however this composite still does not reduce word line resistance to a level comparable to metal gate structures.

The use of metal gate structures can however add process complexity specifically when the metal gate structure is subjected to a salicide procedure which is used to form metal silicide on source/drain regions of a MOSFET or of a CMOS device. The salicide process results in the formation of metal silicide on source/drain regions after metal deposition and annealing procedures, while leaving unreacted metal on the surface of insulator layers such as sidewall insulator spacers located on the sides of the gate structure. Selective removal of unreacted metal via wet etch procedures can however result in unwanted removal or attack of an exposed metal gate structure, resulting in decreased word line resistance.

The present invention will teach a process sequence in which salicide processing is successfully coupled with metal gate structures, without degradation of the metal gate structure during wet etch procedures used to selectively remove unreacted metal from the surface of the sidewall insulator spacers. Prior art such as Besser et al in U.S. Pat. No. 6,436,840 B1, Besser et al in U.S. Pat. No. 6,440,868 B1, as well as Gardner et al in U.S. Pat. No. 6,326,251 B1, describe process sequences in which metal silicide is formed on MOSFET devices comprised with metal gate structures, however these prior art describe process sequences more complex and costly than the simplified process offered in the present invention. In addition prior art such as Nguyen et al in U.S. Pat. No. 6,084,279, and Lin et al in U.S. Pat. No. 6,475,908 B1, describe MOSFET devices featuring metal gate structures however without integration of metal silicide regions. None of the above prior art however describe the unique process sequence offered in the present invention in which a salicide procedure is integrated with metal gate structures in a simplified process sequence and without damage to the metal gate structure during selective removal of unreacted metal.

### SUMMARY OF THE INVENTION

It is an object of this invention to form a MOSFET or CMOS device featuring a metal gate structure on a high k gate insulator layer.

It is another object of this invention to form self -aligned metal silicide regions on both source/drain regions as well as on the top of the metal gate structure.

It is still another object of this invention to employ a thin amorphous silicon region on the top surface of the metal gate structure prior to the salicide procedure to provide a component for formation of a metal silicide shape on the metal gate structure, wherein the overlying metal silicide shape will then subsequently provide protection of the underlying metal gate structure during the wet etch selective removal of unreacted metal.

In accordance with the present invention a method of forming metal silicide regions for a MOSFET device featuring a metal gate structure, is described. After formation of a high k gate insulator layer on a semiconductor substrate, a metal layer is deposited followed by the deposition of a thin amorphous silicon layer. Photolithographic and anisotropic dry etch procedures are used to form a metal gate structure with an overlying amorphous silicon shape, on the high k gate insulator layer. After formation of a lightly doped source/drain (LDD) region in an area of the semiconductor substrate not covered by the metal gate structure, composite insulator spacers are formed only on the sides of the metal gate structure and on the sides of the overlying amorphous silicon shape. After formation of a heavily doped region in an area of the semiconductor substrate not covered by the metal gate structure or by the composite insulator spacers, a blanket metal layer is deposited. An anneal procedure is next employed resulting in formation of metal silicide on the heavily doped source/drain region. The combination of metal on the exposed top surface of the amorphous silicon shape also results in formation of metal silicide on the metal gate structure, while portions of the metal layer located on the composite insulator spacers remain unreacted. Wet etch procedures are used to selectively remove the unreacted portions of metal from the surface of the composite insulator spacers, while metal silicide regions on both source/drain and on the top of the metal gate structure remain unetched, with the metal silicide located on the metal gate structure protecting the underlying metal gate structure during the selective removal procedure.

### BRIEF DESCRIPTION OF THE DRAWINGS

The object and other advantages of this invention are best described in the preferred embodiments with reference to the attached drawings that include:

FIGS. 1-8, which schematically in cross-sectional style show key stages used to fabricate a MOSFET device featuring a metal gate structure and employing a salicide procedure to form metal silicide regions on both source/drain as well as on the metal gate structure, and wherein the metal gate structure is protected during the salicide step used to selectively remove unreacted metal.

### DESCRIPTION OF THE PREFERRED EMBODIMENTS

The method of fabricating a MOSFET device featuring a metal gate structure, and featuring a salicide process used to form metal silicide on a source/drain region as well as on the metal gate structure, and wherein the metal gate structure is protected from the salicide etch back step used to selectively remove unreacted metal, will now be described in detail. Although this invention will be described for an N channel, MOSFET device, it should be understood that this invention can also be applied to a P channel MOSFET device, or to a CMOS device comprised of both N channel and P channel MOSFET devices.

Semiconductor substrate 1, comprised of single crystalline P type silicon, featuring a <100> crystallographic orientation, is used and schematically shown in FIG. 1. Insulator layer 2a, featuring a high dielectric constant (high k), is next formed on semiconductor substrate 1. High k layer 2a, can be comprised of silicon nitride, tantalum oxide, silicon oxynitride, zirconium oxide, hafnium oxide, aluminum oxide, hafnium aluminum oxide or a combination of oxides and silicates of hafnium, zirconium etc,.featuring a dielectric constant greater than 4. High k layer 2a, shown schematically in FIG. 1, is formed at a thickness between about 15 to 150 Angstroms, via chemical vapor deposition (CVD) procedures. Conductive layer 3a, comprised of a refractory metal such as tungsten, molybdenum, tantalum, titanium, or comprised of a metal nitride material, is next formed on high k, gate insulator layer 2a, at a thickness between about 800 to 2000 Angstroms, via physical vapor deposition (PVD) procedures. A critical amorphous silicon layer 4a, is next formed on metal layer 3a, at a thickness between about 200 to 1000 Angstroms, via a low pressure chemical vapor deposition (LPCVD), or via a plasma enhanced chemical vapor deposition (PECVD) procedure. The thickness of amorphous silicon layer 4a, used to protect a subsequently defined metal gate structure from a wet etch procedure used to selectively remove unreacted metal during a salicide procedure, is adjusted to either be fully or partially consumed during the salicide procedure. Photoresist layer 5a, is next applied on amorphous silicon layer 4a. The result of the above procedures is schematically shown in FIG. 1.

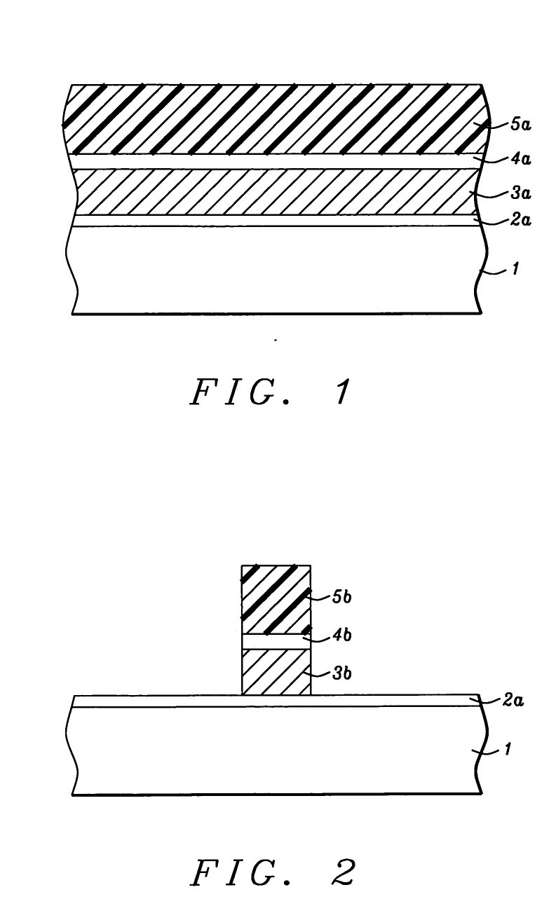

Photolithographic exposure and development procedures are next employed to define photoresist shape 5b, at a width between about 0.05 to 2 micrometers. Using photoresist shape 5b, as an etch mask an anisotropic reactive ion etch (RIE) procedure defines metal gate structure 3b, on high k gate insulator layer 2a. The anisotropic RIE procedure, performed using Cl₂ as an etchant for conductive materials, also allows definition of amorphous silicon shape 4b, overlying metal structure 3b, to be accomplished. The anisotorpic RIE procedure selectively terminates at the appearance of high k gate insulator layer 2a. The result of these procedures is schematically described in FIG. 2.

Removal of photoresist shape 5b, is accomplished via plasma oxygen ashing procedures and wet clean procedures. The wet clean procedures, performed using buffered hydrofluoric acid or dilute hydrofluoric acid as a component, allows removal of the portions of high k gate insulator layer 2a, not covered by metal gate structure 3b, to occur, resulting in only high k gate insulator 2b, now remaining underlying metal gate structure 3b. Lightly doped source/drain (LDD) region 6, is next formed in top portions of semiconductor substrate 1, not covered by the metal gate structure. This is accomplished via implantation of arsenic or phosphorous ions, at an energy between about 0.5 to 10 KeV, at a dose between about 5E14 to 2E15 atoms/cm². This is schematically shown in FIG. 3. If this invention is being applied to a P channel MOSFET device an N well region would be initially formed in a top portion of the semiconductor substrate and a P type LDD region would be formed in top portions of the N well region via implantation of boron or BF₂ ions.

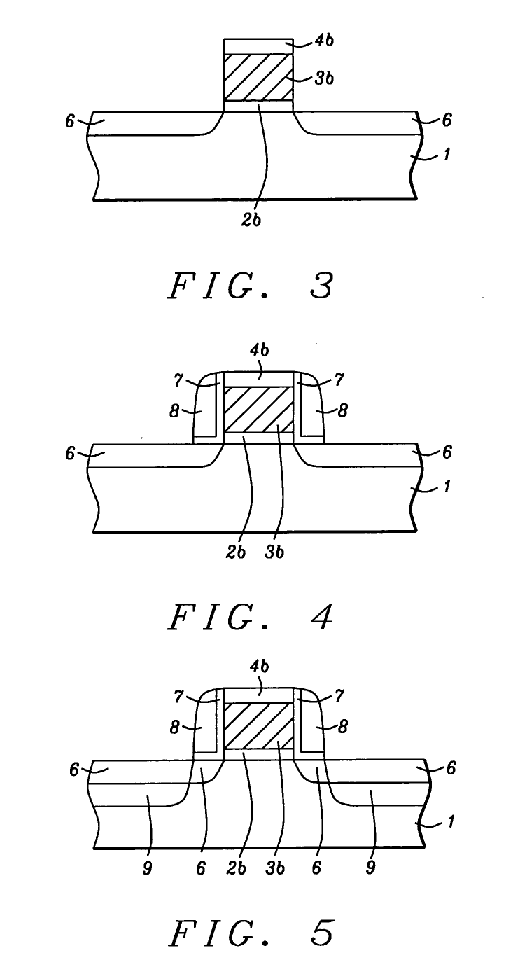

Formation of composite insulator spacers on the sides of metal gate structure 3b, and on the sides of amorphous silicon shape 4b, is next addressed and schematically described in FIG. 4. A silicon oxide layer is first deposited at a thickness between about 50 to 250 Angstroms via LPCVD or PECVD procedures, followed by deposition of an overlying silicon nitride layer obtained at a thickness between about 300 to 1000 Angstroms, again via LPCVD or PECVD procedures. An anisotropic RIE procedure using Cl₂ or CF₄ as a selective etchant for silicon nitride and using CHF₃ as an etchant for silicon oxide, is employed to define the composite insulator spacers comprised of silicon nitride spacers 8, and silicon oxide spacers 7. Encapsulation of metal gate structure 3b, in regards to the sidewall composite insulator spacers as well as overlying amorphous silicon shape 4b, has now been accomplished.

Heavily doped source/drain region 9, shown schematically in FIG. 5, is next formed via implantation of arsenic or phosphorous ions into a region of semiconductor substrate 1, not covered by metal gate structure 3b, or by the composite insulator spacers. Again for this description a heavily doped N type source/drain region obtained at an implant energy between about 30 to 100 KeV, at a dose between about 1E15 to 1E16 atoms/cm² is employed, however if a P channel MOSFET device is desired a P type heavily doped source/drain region, accomplished via implantation of boron or BF₂ ions would be used. Activation of the implanted ions located in both LDD region 6, and heavily doped source/drain region 9, is accomplished via a rapid thermal anneal (RTA) procedure, performed at a temperature between about 900 to 1100° C., for a time between about 0.1 to 5 sec., in an inert ambient.

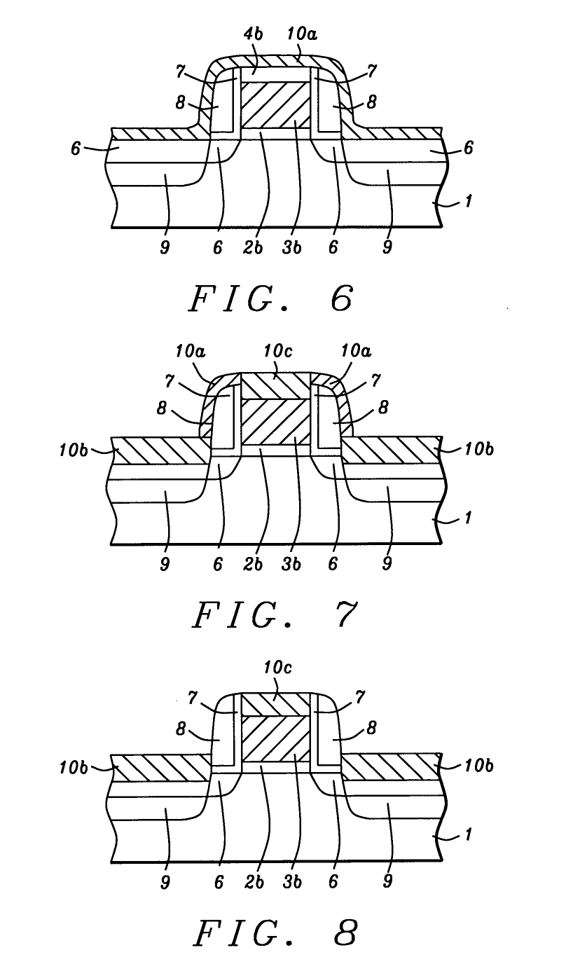

After a pre-clean procedure, performed using dilute hydrofluoric acid, metal layer 10a, a layer such as titanium, cobalt, nickel, zirconium, or tantalum, is deposited via PVD procedures to a thickness between about 50 to 500 Angstroms. If desired metal layer 10a, can be comprised of nickel-platinum. This is schematically shown in FIG. 6.

An RTA procedure is next employed at a temperature between about 450 to 900° C., for a time between about 30 to 400 sec., in an inert ambient such as nitrogen or argon, resulting in formation of metal silicide regions 10b, on heavily doped source/drain region 9. The RTA procedure also results in formation of metal silicide region 10c, located overlying metal gate structure 3b, accomplished via reaction of metal layer 10a, and a portion of amorphous silicon shape 4b. The thickness of amorphous silicon shape 4b, the thickness of metal layer 10a, as well RTA conditions, determine the extent of formation of metal silicide region 10c. If desired the above parameters can be designed to form metal silicide region 10c, on a non-consumed bottom portion of amorphous silicon shape 4b, or as shown schematically in FIG. 7, the above parameters, metal layer and amorphous silicon thickness as well as RTA conditions, can be designed to totally consume amorphous silicon shape 4b. Independent of the level of consumption of amorphous silicon shape 4b, the critical aspect is coverage or protection of the top surface of metal gate structure 3b, providing by metal silicide region 10c, during a subsequent wet etch procedure. Portions of metal layer 10a, located on the composite insulator spacers remain unreacted during the RTA procedure.

Removal of unreacted portions of metal layer 10a, is next addressed via a selective wet etch procedure, performed at a temperature between about 50 to 200° C., using a solution comprised of HCl—H₂O₂—NH₄OH—H₂SO₄. The selective wet etch solution removes metal layer 10a, from the surface of the composite insulator spacers, while metal silicide region 10b, and metal silicide region 10c, are not attacked. If metal silicide region 10c, was not present metal gate structure 3b, would be attacked, eroded or damaged by the wet etch procedure. The presence the amorphous silicon shape allowed formation of metal silicide region 10c, to be realized, in turn offering the protection needed by the metal gate structure during the wet etch procedure employed to remove unreacted metal. The result of this procedure is schematically shown in FIG. 8. If desired another RTA procedure can be performed to lower the resistance of the metal silicide regions.

While this invention has been particularly shown and described with reference to the preferred embodiments thereof, it will be understood by those skilled in the art that various changes in form and details may be made without departing from the spirit and scope of this invention.

1. A method of forming a metal oxide semiconductor field effect transistor (MOSFET)
device on a semiconductor substrate comprising the steps of:
forming a gate insulator layer on said semiconductor substrate;
forming a conductive layer on said gate insulator layer;
forming a semiconductor layer on said conductive layer;
defining a conductive gate structure and an overlying semiconductor shape, on said gate insulator layer;
removing portion of said gate insulator layer not covered by said conductive gate structure;
forming a first doped region in an area of said semiconductor substrate not covered by said conductive gate structure;
forming composite insulator spacers on the sides of said conductive gate structure and on the sides of said semiconductor shape;
forming a second doped region in an area of said semiconductor substrate not covered by said conductive gate structure, or by said composite insulator spacers;
forming a metal layer;
performing an anneal procedure to form first metal silicide regions from an overlying first portion of said metal layer and from a top portion of said second doped region, and to form a second metal silicide region on said conductive gate structure from an overlying second portion of said metal layer via total consumption of said semiconductor shape, while third portions of said metal layer located on said composite insulator spacers remain unreacted; and
removing unreacted portions of said metal layer located on said composite insulator spacers.

2. The method of claim 1, wherein said MOSFET device is an N channel MOSFET device.

3. The method of claim 1, wherein said MOSFET device is a P channel MOSFET device.

4. The method of claim 1, wherein said MOSFET device is a complimentary metal oxide semiconductor (CMOS) device, comprised with both N channel and P channel MOSFET devices.

5. The method of claim 1, wherein said gate insulator layer is a high dielectric constant (high k) layer selected from a group consisting of silicon nitride, tantalum oxide, silicon oxynitride, zirconium oxide, hafnium oxide, aluminum oxide, all with a dielectric constant greater than 4.

6. The method of claim 1, wherein the thickness of said gate insulator layer is between about 15 to 500 Angstroms.

7. The method of claim 1, wherein said conductive layer is a refractory metal such as tungsten or molybdenum, obtained via physical vapor deposition procedures at a thickness between about 800 to 2000 Angstroms.

8. The method of claim 1, wherein said semiconductor layer is an amorphous silicon layer, obtained at a thickness between about 200 to 1000 Angstroms, via a low pressure chemical vapor deposition (LPCVD), or via a plasma enhanced chemical vapor deposition (PECVD) procedure.

9. The method of claim 1, wherein said conductive gate structure and said overlying semiconductor shape are defined via an anisotropic reactive ion etch procedure using Cl₂ as an etchant for said semiconductor layer and for said conductive layer.

10. The method of claim 1, wherein said composite insulator spacers are comprised of an underlying silicon oxide shape at a thickness between about 50 to 250 Angstroms, and an overlying silicon nitride shape at a thickness between about 300 to 1000 Angstroms.

11. The method of claim 1, wherein said metal layer is selected from a group consisting of titanium, cobalt, nickel, zirconium, tantalum, or nickel-platinum, obtained via physical vapor deposition procedures at a thickness between about 50 to 500 Angstroms.

12. The method of claim 1, wherein said anneal procedure used to form metal silicide regions is a rapid thermal anneal procedure performed in an inert ambient at a temperature between about 450 to 900° C., for a time between about 30 to 400 sec.

13. The method of claim 1, wherein second metal silicide region is formed from a top portion of said semiconductor shape, leaving a bottom portion of said semiconductor shape located overlying said conductive gate structure.

14. The method of claim 1, wherein second metal silicide region located on said conductive gate structure, is formed consuming all of said semiconductor shape.

15. The method of claim 1, wherein unreacted portions of said metal layer are removed via a wet procedure using a solution comprised of HCl—H₂O₂—NH₄OH—H₂SO₄.

16. A method of forming a MOSFET device on a semiconductor substrate featuring a metal silicide region on a metal gate structure, comprising the steps of:
forming a high dielectric constant (high k), gate insulator layer on said semiconductor substrate;
forming a first metal layer on said high k gate insulator layer;
forming an amorphous silicon layer on said first metal layer;
performing a first anisotropic reactive ion etch (RIE) procedure to define a metal gate structure and an overlying amorphous silicon shape, on said high k gate insulator layer;
removing portion of said high k gate insulator layer not covered by said metal gate structure;
forming a lightly doped source/drain region in an area of said semiconductor substrate not covered by said metal gate structure;
forming a silicon oxide layer;
forming a silicon nitride layer;
performing a second anisotropic RIE procedure to form composite insulator spacers comprised of an overlying silicon nitride shape and an underlying silicon oxide shape, on the sides of said metal gate structure and on the sides of said amorphous silicon shape;
forming a heavily doped source/drain region in an area of said semiconductor substrate not covered by said metal gate structure, or by said composite insulator spacers;
forming a second metal layer;
performing a first anneal procedure to form first metal silicide regions from an overlying first portion of said second metal layer and from a top portion of said heavily doped source/drain region, and to form a second metal silicide region from an overlying second portion of said metal layer and from said amorphous silicon shape completely consuming said amorphous silicon shape, while a third portion of said second metal layer located on said composite insulator spacers remain unreacted;
removing unreacted third portion of said second metal layer; and
performing a second anneal procedure.

17. The method of claim 16, wherein said MOSFET device is an N channel MOSFET device.

18. The method of claim 16, wherein said MOSFET device is a P channel MOSFET device.

19. The method of claim 16, wherein said MOSFET device is a complimentary metal oxide semiconductor (CMOS) device, comprised with both N channel and P channel MOSFET devices.

20. The method of claim 16, wherein said high k gate insulator layer is selected from a group consisting of silicon nitride, tantalum oxide, silicon oxynitride, zirconium oxide, hafnium oxide, aluminum oxide.

21. The method of claim 16, wherein said high k gate insulator layer is comprised with a dielectric constant greater than 4, and at a thickness between about to 150 Angstroms.

22. The method of claim 16, wherein said first metal layer is a refractory metal such as tungsten or molybdenum, obtained via physical vapor deposition procedures at a thickness between about 800 to 2000 Angstroms.

23. The method of claim 16, wherein said amorphous silicon layer is obtained at a thickness between about 200 to 1000 Angstroms, via a low pressure chemical vapor deposition (LPCVD), or via a plasma enhanced chemical vapor deposition (PECVD) procedure.

24. The method of claim 16, wherein said first anisotropic RIE procedure used to define said metal gate structure and said overlying amorphous silicon shape is performed using Cl₂ as an etchant.

25. The method of claim 16, wherein said silicon oxide layer is obtained via LPCVD or via PECVD procedures at a thickness between about 50 to 250 Angstroms

26. The method of claim 16, wherein said silicon nitride layer is obtained via LPCVD or via PECVD procedures a thickness between about 300 to 1000 Angstroms.

27. The method of claim 16, wherein said second metal layer is selected from a group consisting of titanium, cobalt, nickel, zirconium, tantalum, or nickel-platinum, obtained via physical vapor deposition procedures at a thickness between about 50 to 500 Angstroms.

28. The method of claim 16, wherein said first anneal procedure used to form metal silicide regions is a rapid thermal anneal (RTA) procedure performed in an inert ambient at a temperature between about 450 to 900° C., for a time between about 30 to 400 sec.

29. The method of claim 16, wherein second metal silicide region is formed from a top portion of said amorphous silicon shape, leaving an unreacted bottom portion of said amorphous silicon shape located overlying said metal gate structure.

30. The method of claim 16, wherein second metal silicide region located on said metal gate structure, is formed consuming all of said amorphous silicon shape.

31. The method of claim 16 wherein said unreacted portion of said third metal layer is removed via a wet procedure using a solution comprised of HCl—H₂O₂—NH₄OH—H₂SO₄.
